(19) United States
(12) Patent Application Publication
(10) Pub. No.: US 2016/0293897 A1
(43) Pub. Date: Oct. 6, 2016

(54) OLED DEVICE PACKAGE AND PACKAGING METHOD THEREOF, AND LIGHT-EMITTING DEVICE

(71) Applicants: BOE TECHNOLOGY GROUP CO., LTD., Beijing (CN); HEFEI XINSHENG OPTOELECTRONICS TECHNOLOGY CO., LTD, Hefei City, Anhui (CN)

(72) Inventors: Wei QUAN, Beijing (CN); Chun Jan WANG, Beijing (CN)

(73) Assignee: BOE TECHNOLOGY GROUP CO., LTD., Beijing (CN)

(21) Appl. No.: 14/436,714

(22) PCT Filed: Sep. 2, 2014
(86) PCT No.: PCT/CN2014/085763

§ 371 Date: Apr. 17, 2015

(30) Foreign Application Priority Data
Mar. 10, 2014 (CN) 201410086385.8

(51) Int. Cl. H01L 51/56; H01L 51/52

(52) U.S. Cl. CPC H01L 51/56; H01L 51/5253; H01L 51/5246

(57) ABSTRACT

An OLED device package (01), a packaging method thereof and a lighting-emitting device are provided. The OLED device package (01) comprises: a device substrate (10), a package substrate (20) bonded with the device substrate (10), and an adhesive film (30) disposed between the device substrate (10) and the package substrate (20). The device substrate comprises a base substrate (101) and an OLED device disposed on the base substrate (101). The package (01) further comprises: a buffer layer (40) disposed between the device substrate (10) and the adhesive film (30); A side of the buffer layer in contact with the adhesive film is an uneven surface.

### TECHNICAL FIELD

The present disclosure relates to an OLED device package and a packaging method thereof, and a lighting-emitting device.

### BACKGROUND

In an Organic Light-Emitting Diode (OLED) display, an OLED device is extremely apt to react with components such as vapor and oxygen in air, so the OLED device needs to be strictly isolated from water and oxygen in environment to prolong a service life of the OLED device.

A conventional packaging method comprises two types: substrate packaging and film packaging, wherein the substrate packaging means that an adhesive film is filled between a device substrate provided with the OLED device and a package substrate, and an airtight space is formed between the device substrate and the package substrate after the adhesive film is cured, so as to achieve a package; the film packaging means that a surface of the OLED device is covered by a film packaging layer combined by an inorganic film and an organic film, so that water and oxygen can hardly permeate into the OLED device.

In substrate packaging, as the adhesive film is generally an organic binder and, after cured, a mass of pores are generated, the water and oxygen in air can react with the OLED device through the pores; in film packaging, although the inorganic film with higher density has certain water and oxygen isolating function, defects such as pinholes and cracks generated inevitably during preparing of the inorganic film will greatly reduce the water and oxygen isolating function of the inorganic film; and the inorganic film with lower elasticity and large inner stress easily generates cracks or is separated from the OLED device under an action of an external force, so the inorganic film needs to be laminated together with the organic film to form a composite film; but the organic film has a poor capacity to isolate water and oxygen, and even certain organic film materials per se have stronger water absorbability, which results in that the moisture possibly penetrates defects of the adjacent inorganic film to enter the OLED device.

### SUMMARY OF THE INVENTION

An embodiment of the present disclosure provides an OLED device package, comprising: a device substrate, a package substrate bonded with the device substrate, and an adhesive film disposed between the device substrate and the package substrate, the device substrate comprising a base substrate and an OLED device disposed on the base substrate, wherein, the package further comprises: a buffer layer disposed between the device substrate and the adhesive film; and a side of the buffer layer in contact with the adhesive film is an uneven surface.

Another embodiment of the present disclosure provides a light-emitting device, comprising the package described above.

Still another embodiment of the present disclosure provides a packaging method for an OLED device, comprising: forming a buffer layer on a device substrate comprising a base substrate and an OLED device disposed on the base substrate so as to cover the OLED device; performing a surface treatment on the buffer layer so that the buffer layer has an uneven surface; forming an adhesive film on the buffer layer having the uneven surface, or forming an adhesive film on a package substrate; and bonding the device substrate with the package substrate.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a sectional structural schematic diagram of an OLED device package provided by an embodiment of the present disclosure;

FIG. 2 is an amplified schematic diagram of a dotted part in FIG. 1;

FIG. 3 is a sectional structural schematic diagram of an OLED device package provided by an embodiment of the present disclosure;

FIG. 4 is a schematic diagram of partial optical path of light rays which are upwards emitted from an OLED device in an OLED device package provided by the embodiment of the present disclosure;

FIG. 5 is a partial structural schematic diagram of a package corresponding to a step of a packaging method provided by an embodiment of the present disclosure;

FIG. 6 is a partial structural schematic diagram of the package corresponding to a step of the packaging method provided by the embodiment of the present disclosure;

FIG. 7 is a partial structural schematic diagram of the package corresponding to a step of the packaging method provided by the embodiment of the present disclosure;

FIG. 8 is a partial structural schematic diagram of the package corresponding to a step of the packaging method provided by the embodiment of the present disclosure.

### DESCRIPTION OF THE EMBODIMENTS

The technical solutions of embodiments of the present disclosure will be described in a clearly and fully understandable way in connection with the drawings related to the embodiments of the invention. It is obvious that the described embodiments are just a part but not all of the embodiments of the present disclosure. Based on the described embodiments herein, those skilled in the art can obtain other embodiment(s), without any inventive work, which should be within the scope of the present disclosure.

An embodiment of the present disclosure provides an OLED device package 01; as shown in FIGS. 1-3, the package 01 comprises: a device substrate 10, a package substrate 20 bonded with the device substrate 10, and an adhesive film 30 disposed between the device substrate 10 and the package substrate 20, the device substrate 10 including a base substrate 101 and an OLED device 102 disposed on the base substrate 101; the package 01 further comprises: a buffer layer 40 disposed between the device substrate 10 and the adhesive film 30; wherein a side of the buffer layer 40 in contact with the adhesive film 30 forms into an uneven surface 401.

In the above package 01, as the side of the buffer layer 40 in contact with the adhesive film 30 forms into the uneven surface 401, the buffer layer 40 has a larger surface area on this side, which can enhance soakage of the adhesive film 30 on the uneven surface 401, and reduce an interface gap between the adhesive film 30 and the buffer layer 40, so that the adhesive film 30 and the buffer layer 40 are combined more tightly, a possibility that water and oxygen in environment invade inside the OLED device 102 is reduced, and further a packaging effect of the OLED device 102 is improved and the service life is prolonged.

Here, the buffer layer 40 can comprise at least one of inorganic film and organic film, which is not limited here. The inorganic film can be with large density, for example, SiN, SiO, SiON, Al₂O₃ and the like, and the organic film can be, for example, Polyethylene Terephthalate (PET), Polyethylene Naphthalate (PEN), Polyimide (PI), Polyvinyl Chloride (PVC), Polytetrafluorethylene (PTFE) and the like; besides, the buffer layer 40 can be a composite film formed by alternately laminating the above inorganic film and the above organic film.

In an example, the buffer layer 40 includes at least two mutually laminated films. The uneven surface 401 is only formed on a side of the film of the buffer layer 40 in contact with the adhesive film 30 and farthest away from the OLED device 102.

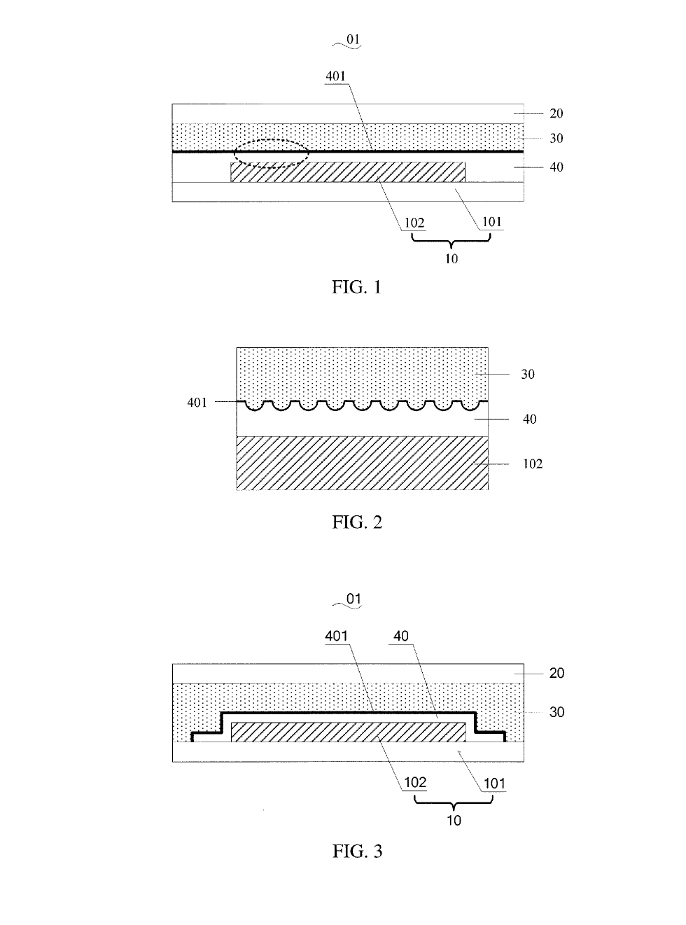

An uneven shape shown in FIG. 2 is just a schematic presentation of the uneven surface 401, and the embodiment of the present disclosure does not limit a microstructure, uniformity or nonuniformity of the unevenness as long as the surface roughness of the buffer layer 40 is increased by the unevenness and the buffer layer has a larger surface area compared with a flat buffer layer.

When a roughness of the uneven surface 401 is too small, enlarging effect of the surface area of the buffer layer 40 is weak; and when the roughness of the uneven surface 401 is too large, a damage to the surface of the buffer layer 40 may be caused, and a normal performance of the buffer layer 40 is influenced. Therefore, the roughness of the uneven surface 401 should be within a proper range.

In an example, the uneven surface 401 has a roughness of 0.04-0.06 μm, which thus can enhance the soakage of the adhesive film 30 on the surface of the buffer layer 40 as much as possible, so as to achieve an increased bonding strength between the buffer layer 40 and the adhesive film 30. For example, the uneven surface 401 has a roughness of 0.05 μm.

Here, the roughness refers to a profile fluctuation degree of the uneven surface 401, namely, within a certain sampling length, for example, 200 μm, of the surface of an object, a distance between the highest peak line and the lowest valley line of the surface contour.

In an example, the buffer layer 40 has a thickness of 0.5-1.5 μm. Here, as the uneven surface 401 of the buffer layer 40 is usually obtained by a certain process treatment, when the thickness of the buffer layer 40 is too small (for example, less than 0.5 μm), it is unfavorable for formation of the uneven surface 401; as the package 01 is often used for structures such as display devices, too large thickness of the buffer layer 40 (for example, greater than 1.5 μm) will result in a too large integral thickness of the package 01, which is unfavorable for lightening and thinning of the display devices. For example, the buffer layer 40 has a thickness of 1.0 μm.

In an example, as shown in FIG. 3, a projection area of the buffer layer 40 on the base substrate 101 is greater than or equal to that of the OLED device 102 on the base substrate 101 and is less than an area of the base substrate 101. The adhesive film 30 fully covers the buffer layer 40 and the regions uncovered by the buffer layer 40 on the base substrate 101.

In such a way, as compared with the case as shown in FIG. 1 where the projection area of the buffer layer 40 on the base substrate 101 is equal to the area of the base substrate 101, the buffer layer 40 in FIG. 3 can be more tightly combined with the adhesive film 30, so as to further improve the sealing effect of the package 01.

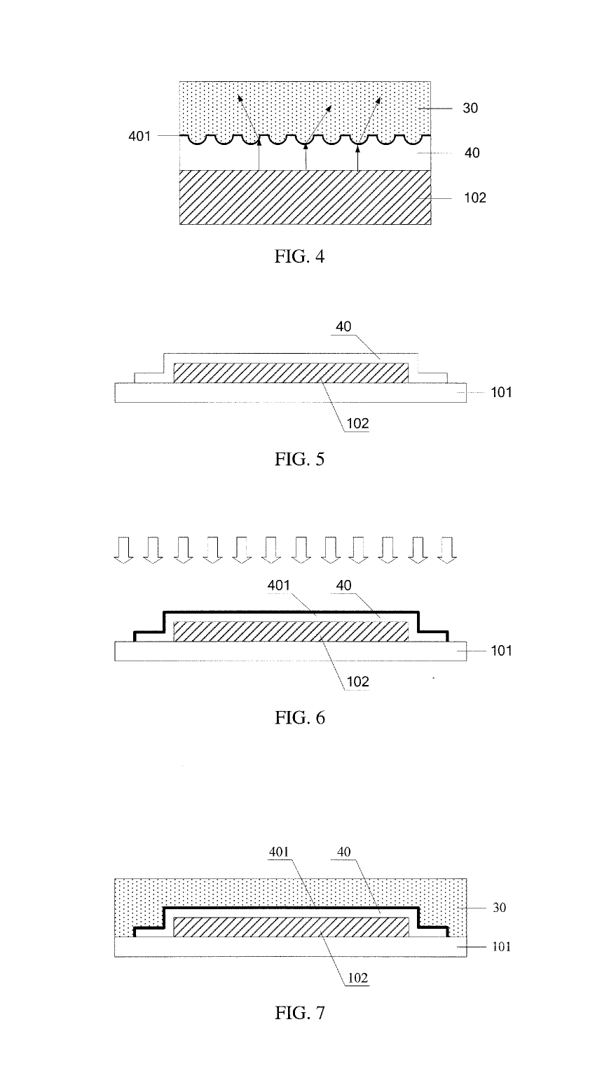

As shown in FIG. 4, the OLED device 102 is a top-emitting OLED, namely, with respect to the base substrate 101 (not shown), the top-emitting OLED has an upward light-emitting direction; or the OLED device 102 is a double-sided-emitting OLED, namely, with respect to the base substrate 101 (not shown), and the double-sided-emitting OLED has an upward light-emitting direction and a downward light-emitting direction. The uneven surface 401 can not only enhance the bonding strength between the buffer layer 40 and the adhesive film 30, but also improve a scattering degree of light emitted from the OLED device 102 when passing through the uneven surface 401, so that light transmissivity of the top-emitting OLED or that of the upward side of the double-sided-emitting OLED is enlarged.

In an example, the buffer layer 40, the adhesive film 30 and the package substrate 20 all have a transparent material with high light transmissivity, so light emitted from the top-emitting OLED or from the upward side of the double-sided-emitting OLED sequentially passes through the buffer layer 40, the adhesive film 30 and the package substrate 20 and further exit the package.

It should be noted that, in order to enable the uneven surface 401 to enlarge the bond strength between the buffer layer 40 and the adhesive film 30 on one hand, and improve the light transmissivity of the top-emitting OLED or the upward side of double-sided-emitting OLED on the other hand, the roughness scope of the uneven surface 401 can be adjusted according to parameters such as material and size of the buffer layer 40, which is not limited here.

An embodiment of the present disclosure further provides a light-emitting device, comprising any package 01 described above.

Here, the light-emitting device can be light-emitting device which is applied to any of OLED display, organic transistor, organic integrated circuit, organic solar cell, organic laser and/or organic sensor.

Herein, the OLED display, for example, can be any product and part with a display function, such as an OLED display panel, electronic paper, cell phone, tablet PC, television, display, laptop, digital picture frame, navigator, etc.

An embodiment of the present disclosure further provides a packaging method for an OLED device, the method comprising steps of:

S01: as shown in FIG. 5, forming a buffer layer 40 on a device substrate 10 so as to cover an OLED device 102.

wherein, the device substrate 10 includes a base substrate 101 and the OLED device 102 disposed on the base substrate 101.

S02: as shown in FIG. 6, performing a surface treatment on the buffer layer 40 so that a side of the buffer layer 40 facing away from the device substrate 10 forms into an uneven surface 401.

Here, the surface treatment, for example, can be that plasma carrying high energy bombards an outer surface of the buffer layer 40 with respect to the OLED device 102 and finely etches the surface of the buffer layer 40 so as to obtain the uneven surface 401.

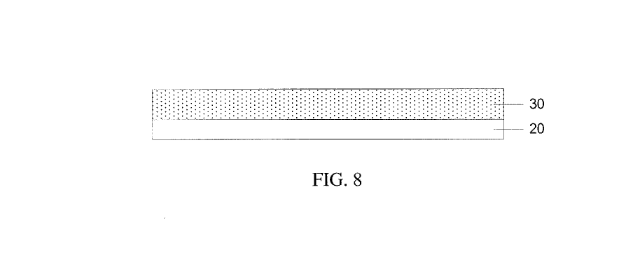

S03: as shown in FIG. 7, forming an adhesive film 30 on the buffer layer 40 having the uneven surface 401, or as shown in FIG. 8, forming the adhesive film 30 on a package substrate 20.

S04: bonding the device substrate 10 with the package substrate 20 thus formed so as to form the package 01 as shown in FIG. 3.

In the step S01, when the package 01 is applied to the Organic Light-Emitting Diode (OLED) display, the OLED device 102 in the package 01, for example, can comprise: an anode layer, a cathode layer and an organic material functional layer; wherein the organic material functional layer, for example, can include: a hole injection layer, a hole transport layer, a light-emitting layer, an electron transport layer and an electron injection layer.

In addition, considering that the OLED device 102 is relatively sensitive to temperature, when the buffer layer 40 is formed, for example, by using an evaporating method, a high temperature in evaporating process easily exerts influence to a performance of the OLED device 102, so in step S01, it is better that the buffer layer 40 is formed by a preparing method with lower film forming temperature or a smaller temperature rising degree of the substrate during film forming process, for example, the buffer layer 40 can be formed by a chemical vapor deposition method, a plasma enhanced chemical vapor deposition method, or a sputtering method.

For example, the buffer layer 40 can be formed by using a plasma enhanced chemical vapor deposition (PECVD) method with advantages such as low film forming temperature, fast deposition speed and controllable film forming stress.

In the step S02, when the buffer layer 40 includes at least two films, the performing a surface treatment on the buffer layer 40 means that performing the surface treatment on an outmost surface of the buffer layer 40, namely, the surface in contact with the adhesive film 30 to be formed.

In the step S04, in the case that the adhesive film 30 is formed on the package substrate 20, a certain uniform laminating force can be applied to the device substrate 10 and/or the package substrate 20 after the device substrate 10 and the package substrate 20 are bonded, so that the adhesive film 30 formed on the package substrate 20 can be in full contact with the uneven surface 401 of the buffer layer 40, and the bonding strength of the two is improved.

Furthermore, considering that inert gas has larger atomic radius, when inert gas plasma particles carrying high energy bombard the surface of the buffer layer 40, the surface of the buffer layer 40 can be etched to a certain extent so as to form the uneven surface, so in an example, in the step S02, the performing a surface treatment on the buffer layer 40 comprises: performing inert gas plasma treatment on the side of the buffer layer facing away from the OLED device 102.

Herein, the inert gas comprises at least one of helium(He), neon(Ne), argon(Ar), krypton(Kr), xenon(Xe) and radon(Rn), that is, the inert gas can be any gas mentioned above and can also be a mixed gas thereof mixed according to any ratio, which is not limited here.

Herein, parameters such as radiofrequency power and etching time involved in the inert gas treatment can be flexibly adjusted according to parameters such constituent material, thickness, area, etc. of the buffer layer 40.

It should be noted that the inert gas plasma treatment is also applicable to a patterning treatment of a film, namely, the film is etched by the inert gas plasma with high energy so as to obtain a pattern layer with certain pattern. In the packaging method provided by the embodiment of the present disclosure, only the surface of the buffer layer 40 needs to be finely etched by the inert gas plasma treatment, so that the buffer layer is provided with the uneven surface 401.

Therefore, as compared with the plasma treatment adopted in the etching process of film patterning treatment, the radiofrequency power of the plasma adopted in the inert gas plasma treatment in the packaging method provided by the embodiment of the present disclosure can be properly reduced by 50%, for example, 7000 watts (based on G6 equipment) and the etching time is controlled, for example, within 10 seconds, so as to avoid damage to an organic material functional layer since the inert gas plasma carrying too high energy or too long time inert gas plasma treatment results in invasion of the inert gas plasma particles carrying high energy into the OLED device 102.

In addition, the microstructure of the uneven surface 401, obtained by the inert gas plasma treatment, of the buffer layer 40, can be observed by an atomic force microscope (AFM), so as to timely adjust the process parameters such as radiofrequency and etching time which are involved in the inert gas plasma treatment and avoid too small or too large roughness of the uneven surface 401 formed.

The method, for example, can further comprises: in the step S04, the adhesive film 30 disposed between the device substrate 10 and the package substrate 20 is cured by ultraviolet irradiation or heating.

Wherein, when the adhesive film 30 is a UV curing adhesive, the adhesive film 30 is cured by ultraviolet irradiation. The adhesive film 30 can absorb ultraviolet light energy under the ultraviolet irradiation, and generate radicals or anions, so that a series of chemical reactions occur inside the adhesive film 30 and the adhesive film 30 is finally cured.

When the adhesive film 30 is a thermoset adhesive (for example, thermoset phenolic resin), the adhesive film 30 can be cured by heating. The adhesive film 30 generates chemical reaction after being heated and is gradually cured and shaped, and is not softened after reheated.

Here, if the adhesive film 30 is cured in the above heating mode, as the OLED device 102 is relatively temperature sensitive, heat of a heating source should be transferred into the adhesive film 30 through the package substrate 20 as much as possible, so as to avoid the influence of high temperature on the organic functional layer in the OLED device 102.

Through the above packaging steps S01-S04, the package 01 as shown in FIG. 3 can be formed.

In the package 01, as the side of the buffer layer 40 in contact with the adhesive film 30 forms into the uneven surface 401 by surface treatment, namely, the buffer layer 40 has a larger surface area, which can enhance soakage of the adhesive film 30 on the uneven surface 401, and reduce an interface gap between the adhesive film 30 and the buffer layer 40, so that the adhesive film 30 and the buffer layer 40 are combined more tightly, a possibility that water and oxygen in environment invade inside the OLED device 102 is reduced, and further a packaging effect of the OLED device 102 is improved and the service life is prolonged.

It should be noted that all the accompanying drawings of the present disclosure are brief schematic diagrams of the package 01, and are just used for clearly describing the present solution embodying the structures related to the present disclosure point, and for other related structures not shown, corresponding existing structures can be adopted, and unnecessary details are not given herein.

According to the above description, the embodiments according to the present disclosure at least can provide structures and methods as follows:

(1) An OLED device package, comprising: a device substrate, a package substrate bonded with the device substrate, and an adhesive film disposed between the device substrate and the package substrate, the device substrate comprising a base substrate and an OLED device disposed on the base substrate, wherein,

the package further comprises: a buffer layer disposed between the device substrate and the adhesive film; and a side of the buffer layer in contact with the adhesive film is an uneven surface.

(2) The package according to (1), wherein the uneven surface has a roughness of 0.04-0.06 μm.

(3) The package according to (1) or (2), wherein the buffer layer has a thickness of 0.5-1.5 μm.

(4) The package according to any one of (1) to (3), wherein a projection area of the buffer layer on the base substrate is greater than or equal to that of the OLED device on the base substrate and is less than an area of the base substrate;

the adhesive film covers the buffer layer, and all other regions not covered by the buffer layer on the base substrate.

(5) The package according to any one of (1) to (3), wherein the OLED device is a top-emitting OLED or a double-sided-emitting OLED;

the buffer layer, the adhesive film and the package substrate are all made of transparent material.

(6) A light-emitting device, comprising the package according to any one of (1) to (5).

(7) A packaging method for an OLED device, comprising:

forming a buffer layer on a device substrate comprising a base substrate and an OLED device disposed on the base substrate so as to cover the OLED device;

performing a surface treatment on the buffer layer so that the buffer layer has an uneven surface;

forming an adhesive film on the buffer layer having the uneven surface, or forming an adhesive film on a package substrate; and

bonding the device substrate with the package substrate.

(8) The packaging method according to (7), wherein the performing a surface treatment on the buffer layer comprising:

performing an inert gas plasma treatment on a side of the buffer layer facing away from the OLED device.

(9) The packaging method according to (8), wherein the inert gas includes at least one of helium, neon, argon, krypton, xenon and radon.

(10) The packaging method according to any one of (7) to (9), wherein after the bonding the device substrate with the package substrate, the method further comprises:

curing the adhesive film between the device substrate and the package substrate by ultraviolet irradiation or heating.

Although the present disclosure is described in detail hereinbefore with general illustration and embodiments, based on the present disclosure, certain amendments or improvements can be made thereto, which is obvious for those skilled in the art. Therefore, the amendments or improvements made on the present disclosure without departing from the spirit of the present disclosure should be within the scope of the present disclosure.

The present application claims priority of Chinese Patent Application No. 201410086385.8 filed on Mar. 10, 2014, the disclosure of which is incorporated herein by reference in its entirety as part of the present application.

1. An OLED device package, comprising: a device substrate, a package substrate bonded with the device substrate, and an adhesive film disposed between the device substrate and the package substrate, the device substrate comprising a base substrate and an OLED device disposed on the base substrate, wherein,
the package further comprises: a buffer layer disposed between the device substrate and the adhesive film; and a side of the buffer layer in contact with the adhesive film is an uneven surface.

2. The package according to claim 1, wherein the uneven surface has a roughness of 0.04˜0.06 μm.

3. The package according to claim 1, wherein the buffer layer has a thickness of 0.5˜1.5 μm.

4. The package according to claim 1, wherein a projection area of the buffer layer on the base substrate is greater than or equal to that of the OLED device on the base substrate and is less than an area of the base substrate;
the adhesive film covers the buffer layer, and all other regions not covered by the buffer layer on the base substrate.

5. The package according to claim 1, wherein the OLED device is a top-emitting OLED or a double-sided-emitting OLED;
the buffer layer, the adhesive film and the package substrate are all made of transparent material.

6. A light-emitting device, comprising the package according to claim 1.

7. A packaging method for an OLED device, comprising:
forming a buffer layer on a device substrate comprising a base substrate and an OLEO device disposed on the base substrate so as to cover the OLED device;
performing a surface treatment on the buffer layer so that the buffer layer has an uneven surface;
forming an adhesive film on the buffer layer having the uneven surface, or forming an adhesive film on a package substrate; and
bonding the device substrate with the package substrate.

8. The packaging method according to claim 7, wherein the performing a surface treatment on the buffer layer comprising:
performing an inert gas plasma treatment on a side of the buffer layer facing away from the OLED device.

9. The packaging method according to claim 8, wherein the inert gas includes at least one of helium, neon, argon, krypton, xenon and radon.

10. The packaging method according to claim 7, wherein after the bonding the device substrate with the package substrate, the method further comprises:
curing the adhesive film between the device substrate and the package substrate by ultraviolet irradiation or heating.

11. The package according to claim 2, wherein the buffer layer has a thickness of 0.5˜1.5 μm.

12. The package according to claim 2, wherein a projection area of the buffer layer on the base substrate is greater than or equal to that of the OLED device on the base substrate and is less than an area of the base substrate.

13. The package according to claim 3, wherein a projection area of the buffer layer on the base substrate is greater than or equal to that of the OLED device on the base substrate and is less than an area of the base substrate.

14. The package according to claim 2, wherein the OLED device is a top-emitting OLEO or a double-sided-emitting OLED;
the buffer layer, the adhesive film and the package substrate are all made of transparent material.

15. The package according to claim 3, wherein the OLED device is a top-emitting OLED or a double-sided-emitting OLED;
the buffer layer, the adhesive film and the package substrate are all made of transparent material.

16. The packaging method according to claim 8, wherein after the bonding the device substrate with the package substrate, the method further comprises:
curing the adhesive film between the device substrate and the package substrate by ultraviolet irradiation or heating.

17. The packaging method according to claim 9, wherein after the bonding the device substrate with the package substrate, the method further comprises:
curing the adhesive film between the device substrate and the package substrate by ultraviolet irradiation or heating.
